(19) United States
(12) Patent Application Publication
(10) Pub. No.: US 2007/0222465 A1
(43) Pub. Date: Sep. 27, 2007

(54) Probe head with vertical probes, method for manufacturing the probe head and probe card using the probe head

(75) Inventors: Hsiang-Ming Huang, Tainan (TW); An-Hong Liu, Tainan (TW); Yi-Chang Lee, Tainan (TW); Yao-Jung Lee, Tainan (TW)

Correspondence Address: TROXELL LAW OFFICE PLLC, SUITE 1404, 5205 LEESBURG PIKE, FALLS CHURCH, VA, 22041, US

(73) Assignees: ChipMOS Technologies (Bermuda) Ltd.; ChipMOS Technologies Inc.

(21) Appl. No.: 11/599,612

(22) Filed: Nov. 15, 2006

(30) Foreign Application Priority Data
Jan. 17, 2006 (TW) 095102204

(51) Int. Cl. G01R 31/02

(52) U.S. Cl. 324/754

(57) ABSTRACT

A vertical probe head primarily comprise a substrate, a trace layer, and a plurality of vertical probes where the substrate has a first surface, a second surface, and a plurality of device holes penetrating through the first surface and the second surface. The trace layer is formed on the first surface. Each vertical probe has a bonding end and a probing end where the bonding ends are inserted into the device holes of the substrate and are electrically connected to the trace layer and the probing ends are protruded away from the second surface of the substrate. Resins are filled into the device holes to firmly fix the vertical probes so that the vertical probes will not easily be bent nor damaged.

### FIELD OF THE INVENTION

The present invention relates to a key component for semiconductor IC testing, and more particularly, to a vertical probe head and its manufacturing method.

### BACKGROUND OF THE INVENTION

In the conventional IC testing, a probe card has a plurality of probes used to probe the external terminals of untested IC chips to verify whether the electrical properties of the IC chips meet the design specifications or not. Since the features sizes of the semiconductor devices have continuously been shrunk, conventional cantilever (epoxy) type probe cards are gradually replaced by vertical type probe cards where a vertical probe head is directly connected to a printed circuit board.

As shown in FIG. 1, a known vertical type probe card 100 mainly includes a ceramic substrate 110 and a plurality of vertical probes 120 where the ceramic substrate 110 has a top surface 111 and a bottom surface 112. A plurality of contacting pads 113 are formed on the top surface 111 of the ceramic substrate 110 where the contacting pads 113 are designed for placing the probes 120. However, since the ceramic substrate 110 is manufactured by printing, punching, laminating, and sintering, the line widths and spacing of the internal circuits (not shown in the figure) and the pitches of the contacting pads 113 can not meet the ones of the aggressive shrinking of IC chips. Therefore, the known vertical probe card 100 can not probe high-density bonding pads of IC chips with smaller pitches and smaller pad dimensions. Moreover, since only one end of the vertical probe 120 is connected to the contacting pad 113 on the top surface of the ceramic substrate 110, after repeatedly probing the external terminals of untested IC chips, the probes 120 can easily be bent or damaged and the joints between the probes 120 and the contacting pads 113 can easily be broken or delaminated.

### SUMMARY OF THE INVENTION

The main purpose of the present invention is to provide a vertical probe head with its manufacturing processes and the related modularized probe card. A substrate has a plurality of device holes penetrating through the first surface and the second surface so that a plurality of bonding ends of a plurality of vertical probes are inserted into the device holes and are electrically connected to the corresponding traces of the substrate. A plurality of probing ends of the vertical probes are protruded away from the second surface of the substrate. Moreover, the vertical probes are bonded to the device holes by epoxy resin so that the vertical probes can be firmly fixed and can not easily be bent nor damaged.

The second purpose of the present invention is to provide a vertical probe head with its manufacturing processes and the related modularized probe card where the substrate may be a dielectric substrate such as mica, quartz, or glass, or a semiconductor substrate such as Si, GaAs, or GaGe, or a rigid substrate such as ceramic, FR-3, FR-4, FR-5, or BT, or a flexible substrate such as PI so that the pitches between the vertical probes can be greatly reduced by using MEMS processes.

According to the present invention, a vertical probe head primarily comprises a substrate, a trace layer, and a plurality of vertical probes where the substrate has a first surface, a second surface, and a plurality of device holes penetrating through the first surface and the second surface. The trace layer is formed on the first surface of the substrate. Each vertical probe has a bonding end and a probing end where the bonding ends are inserted into the device holes and are electrically connected to the trace layer and the probing ends are protruded away from the second surface of the substrate.

### DESCRIPTION OF THE DRAWINGS

FIG. 1 shows a cross sectional view of a conventional vertical probe head.

FIG. 2 shows a cross sectional view of a vertical probe head according to the first embodiment of the present invention.

FIGS. 3A to 3F show cross sectional views of the vertical probe head during the manufacturing processes according to the first embodiment of the present invention.

FIG. 4 shows a cross sectional view of the vertical probes having the probing ends connecting to the same connecting bar according to the first embodiment of the present invention.

FIG. 5 shows a cross sectional view of a modularized probe card assembled with the vertical probe head according to the first embodiment of the present invention.

FIG. 6 shows a cross sectional view of another vertical probes placed inside a plurality of device holes of a substrate according to the second embodiment of the present invention.

FIG. 7 shows a cross sectional view of the vertical probes having the bonding ends connecting to the same connecting bar according to the second embodiment of the present invention.

FIG. 8 shows a cross sectional view of the vertical probes with a substrate according to the third embodiment of the present invention.

FIG. 9 shows a cross sectional view of the vertical probes bonded inside the device holes of the substrate according to the third embodiment of the present invention.

FIG. 10 shows a cross sectional view of a modularized probe card assembled with the vertical probe head according to the third embodiment of the present invention.

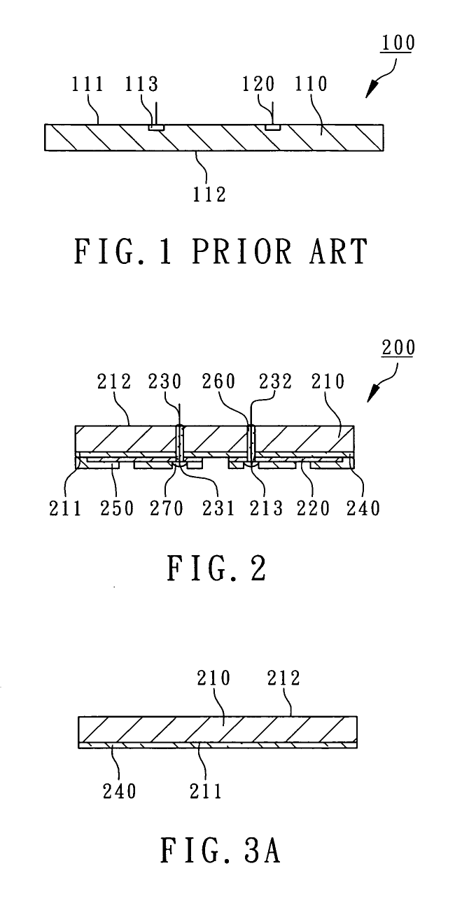

### DETAIL DESCRIPTION OF THE INVENTION

Please refer to the attached drawings, the present invention will be described by means of embodiment(s) below.

According to the first embodiment of the present invention, a vertical probe head 200, as shown in FIG. 2, comprises a substrate 210, a trace layer 220, and a plurality of vertical probes 230 where the substrate 210 can be a dielectric substrate such as mica, quartz, or glass, or a semiconductor substrate such as Si, SiGe, GaAs, or GaGe, or a rigid substrate such as ceramic, FR-3, FR-4, FR-5, or BT, or a flexible substrate such as PI. The substrate 210 has a first surface 211, a second surface 212, and a plurality of device holes 213 penetrating through the first surface 211 and the second surface 212. The pitches between the device holes 213 can be greatly reduced by using MEMS processes. The trace layer 220 is formed on the first surface 211 of the substrate 210 where the materials of the trace layer 220 can be copper, gold, aluminum, silver, palladium. The device holes 213 may be formed by laser drilling, chemical etching, or mechanical punching. Moreover, at least an insulation layer 240 is formed adjacent the first surface 211 of the substrate 210 to electrically isolate the trace layer 220 and the core of the substrate 210. In the present embodiment, the insulation layer 240 is PI. Each vertical probe 230 has a bonding end 231 and a probing end 232 where the vertical probes 230 are formed by MEMS processes rows by rows. The bonding ends 231 of the vertical probes 230 are inserted into the device holes 213 of the substrate 210 and are electrically connected to the corresponding trace layer 220 by a plurality of soldering materials 270 where resins 260 are filled inside the device holes 213 to firmly fix the vertical probes 230. In the present embodiment, the resin 260 is non-conductive paste (NCP). The probing ends 232 are protruded away from the second surface 212 of the substrate 210 to probe the external terminals of untested IC chips, not shown in the figure. The materials of the vertical probes 230 can be chosen from a group of nickel, gold, copper, tungsten, titanium, palladium, silver, cobalt, molybdenum, iron, or their alloys. Preferably, the sidewalls of the device holes 213 are dielectric by certain isolation processes to prevent electrical shorts or signal interference between the substrate 210 and the vertical probes 230. Furthermore, the trace layer 220 is covered by a passivation 250 to protect the traces and to prevent flooding of the soldering materials 270 during reflow. Since the vertical probes 230 are inserted into the device holes 213 and are sealed by resins 260, so that the vertical probes 230 are firmly fixed and will not easily be bent or damaged.

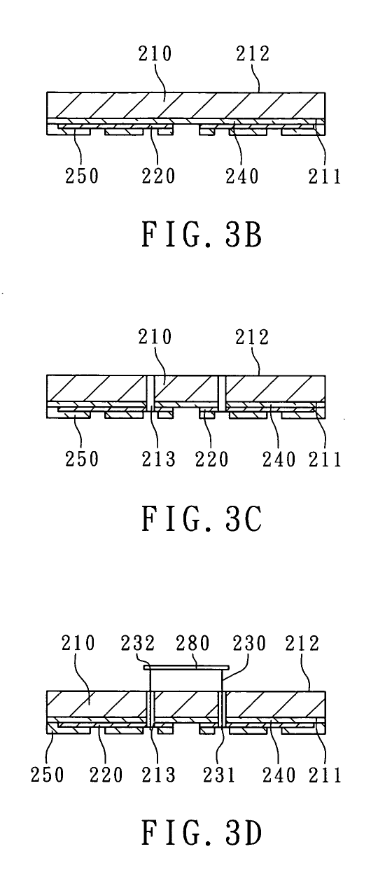

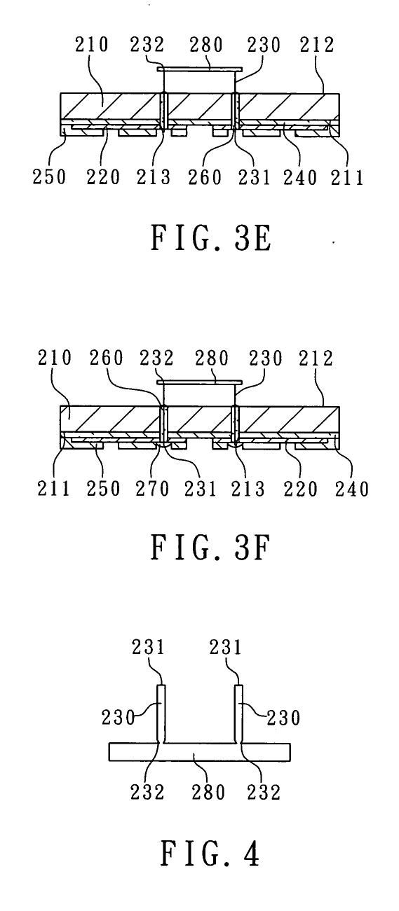

A manufacturing process of the vertical probe head 200 is revealed from FIG. 3A to 3F. Firstly, as shown in FIG. 3A, a substrate 210 is provided where the substrate 210 has a first surface 211 and a second surface 212. An isolation layer 240 is formed on the first surface 211 of the substrate 210. In the present embodiment, the isolation layer 240 is PI. Then, as shown in FIG. 3B, a trace layer 220 is formed on the isolation layer 240 on the first surface 211 of the substrate 210 and then a passivation 250 is formed on the trace layer 220 and is patterned. Afterward, as shown in FIG. 3C, a plurality of device holes 213 are formed to penetrate through the first surface 211 and the second surface 212 by laser drilling. Then, as shown in FIG. 3D, at least a raw of vertical probes 230 are connected to the same connecting bar 280 where each vertical probe 230 has a bonding end 231 and a probing end 232. In the present embodiment, as shown in FIG. 4, the probing ends 232 of the vertical probes 230 are integrally connected to the same connecting bar 280 so that the bonding ends 231 of the vertical probes 230 are inserted into the device holes 213 of the substrate 210 from the second surface 212 of the substrate 210 with the probing ends 232 of the vertical probes 230 protruding away from the second surface 212 of the substrate 210 (as shown in FIG. 3D). Afterward, as shown in FIG. 3E, resins 260 are filled into the device holes 213 to firmly fix the vertical probes 230. Then, as shown in FIG. 3F, a plurality of soldering materials 270 are formed on the bonding ends 231 of the vertical probes 230 by printing. After reflow, the vertical probes 230 are electrically connected to the trace layer 220. With the patterned passivation 250, the soldering materials 270 will not contaminate the trace layer 220. Finally, the connecting bar 280 is removed. As shown in FIG. 2, a vertical probe head 200 is manufactured.

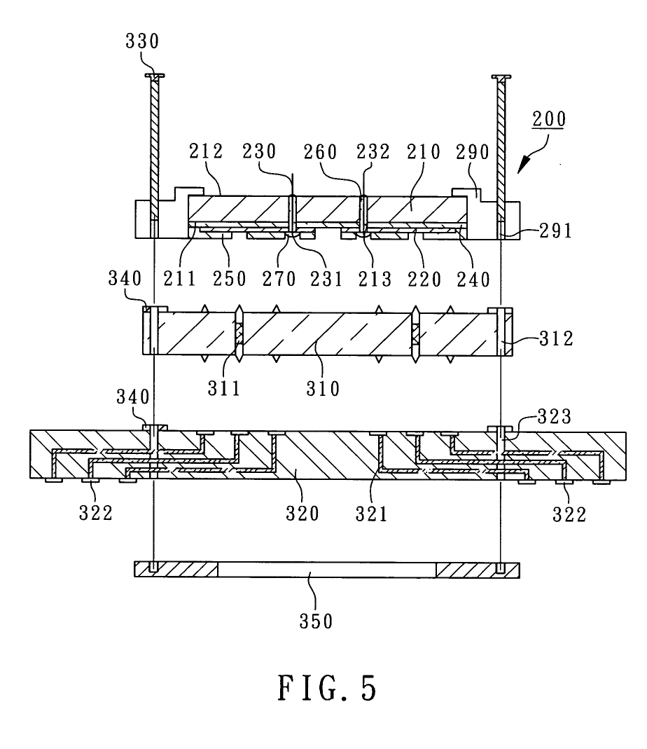

Furthermore, as shown in FIG. 5, according to the first embodiment of the present invention, the vertical probe head 200 can assemble with an interposer 310 and a printed circuit board 320 to form a modularized probe card. The vertical probe head 200 comprises the substrate 210, the trace layer 220, and the plurality of vertical probes 230 where the trace layer 220 is formed on the first surface 211 of the substrate 210. Each vertical probe 230 has the bonding end 231 and the probing end 232. In the present embodiment, the bonding ends 231 are inserted into the device holes 213 from the second surface 212 of the substrate 210 and are electrically connected to the trace layer 220 by a plurality of soldering materials 270. The probing ends 232 are protruded away from the second surface 212 of the substrate 210 for probing external terminals of untested IC chips.

The interposer 310 includes a plurality of electrical contacting components 311 such as pogo pins where the layout of the electrical contacting components 311 is corresponding to the one of the contacting pads of the substrate 210, not shown in the figure, and to the one of the inner pads of the printed circuit board 320, not shown in the figure. Accordingly, the contacting pads of the trace layer 220 of the substrate 210 are electrically connected to the inner pads of the printed circuit board by the interposer 310. A plurality layers of internal circuits 321 and a plurality of pogo pads 322 are formed in the printed circuit board 320 for electrical connections between the modularized probe card and the test head of a tester. The vertical probe head 200 further includes an assembling support 290 which is connected to the peripheries of the substrate 210 with a plurality of through holes 291. Furthermore, the modularized probe card further includes a plurality of fixing elements 330 such as screwed plugs, where the vertical probe head 200, the interposer 310, and the printed circuit board 320 are assembled into a modularized probe card by placing the fixing elements 330 through the through holes 291 of the assembling support 290, through a plurality of through holes 312 of the interposer 310, and through a plurality of bonding holes 323 of the printed circuit board 320, then to the fixing holes of a pressure plate 350 on the other side of the printed circuit board 320. Preferably, O-rings 340 are placed between the substrate 210 and the interposer 310 and between the interposer 310 and the printed circuit board 320 to assure a close contact among the substrate 210, the interposer 310, and the printed circuit board 320.

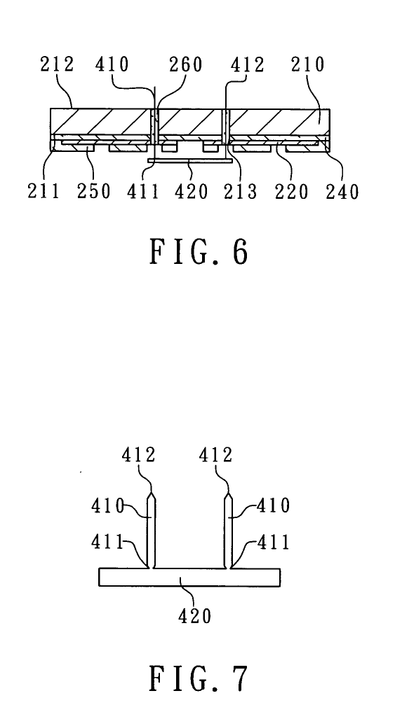

Another method for manufacturing the vertical probe head mentioned above is revealed in FIGS. 6 and 7 according to the second embodiment of the present invention. A plurality of bonding ends 411 of the vertical probes 410 are connected to a same connecting bar 420. In the present embodiment, a plurality of probing ends 412 of the vertical probes 410 are inserted into the device holes 213 of the substrate 210 from the first surface 211 and are protruded away from the second surface 412 of the substrate 210 for probing external terminals of untested IC chips, not shown in the figure. Resins 260 are filled into the device holes 213 to firmly fix the vertical probes 410 after curing. The rest of the manufacturing processes are the same as the ones in the first embodiment. When the connecting bar 420 is removed, a plurality of soldering materials, not shown in the figure, may be formed at the bonding ends 411. After reflowing, the vertical probes 410 are electrically connected to the trace layer 220. The patterned passivation 250 can prevent the flooding of the soldering materials to contaminate the trace layer 220. A vertical probe head is manufactured after removing the connecting bar 420.

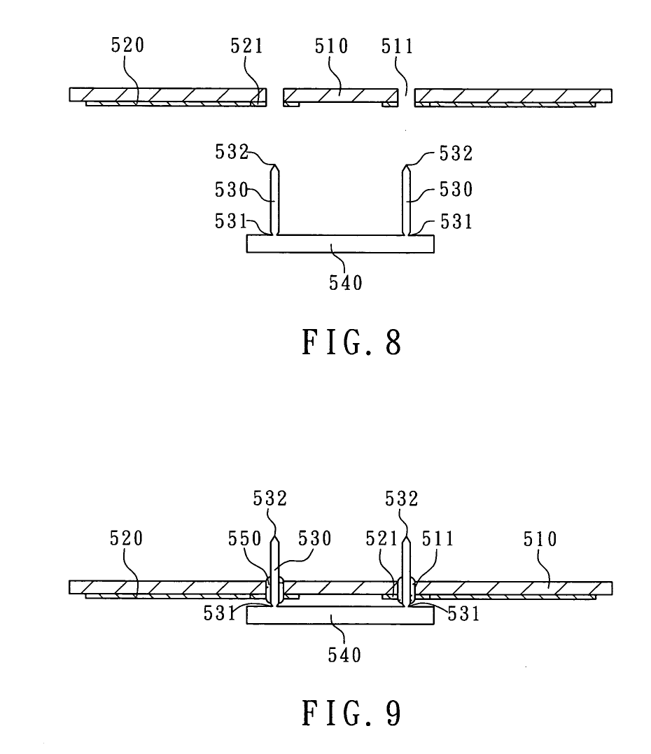

Further more, another method for manufacturing a vertical probe head is revealed in FIGS. 8 and 9 according to the third embodiment of the present invention. As shown in FIG. 8, a substrate 510 is provided where the substrate 510 has a plurality of device holes 511, penetrating through the top surface and the bottom surface of the substrate 510, and a trace layer 520 formed on the substrate. In the present embodiment, the substrate 510 is a flexible printed circuit board having high-density traces and contacting pads 521 around the device holes 511. Before probe placement, a plurality of vertical probes 530 are connected to the same connecting bar 540 where each vertical probe 530 has a bonding end 531 and a probing end 532. Then, as shown in FIG. 9, the probing ends 532 of the vertical probes 530 are inserted into and pass the device holes 511 of the substrate 510 and are protruded away from the substrate 510 for probing external terminals of untested IC chips. Resins 550 are filled into the device holes 511 and cured to firmly fix the bonding ends 531 of the vertical probes 530. In the present embodiment, the resins 550 are conductive paste so that the vertical probes 530 are electrically connected to the contacting pads 521 or other plated through holes of the trace layer 520, not shown in the figure. Finally, the vertical probe head 500 is manufactured after removing the connecting bar 540.

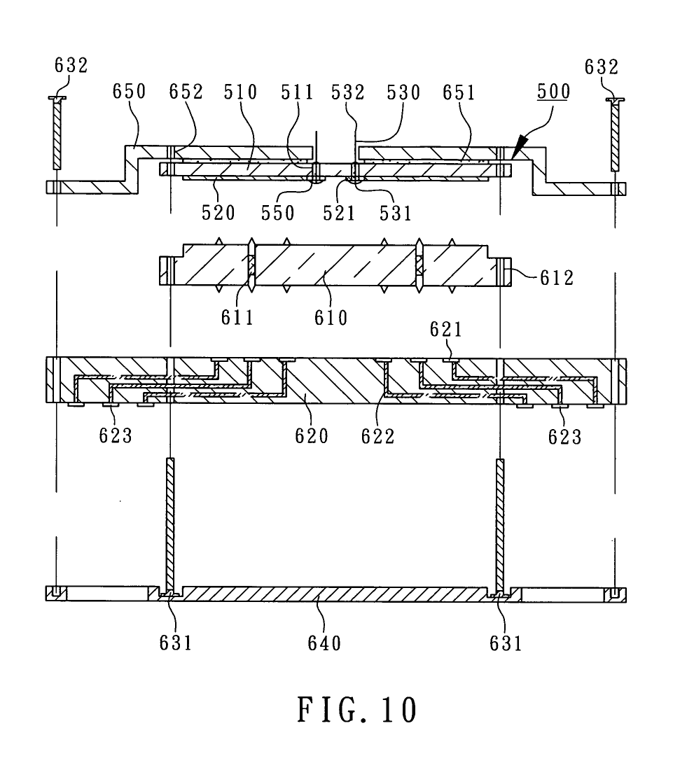

According to the third embodiment of the present invention, as shown in FIG. 10, another modularized probe card is formed by assembling a vertical probe head 500 to an interposer 610 and to a printed circuit board 620. The vertical probe head 500 comprises the flexible substrate 510, the trace layer 520, and the plurality of vertical probes 530. The trace layer 520 is formed on the substrate 510 and has a plurality of contacting pads 521. Each vertical probe 530 has a bonding end 531 and a probing end 532. Resins 550 is filled into the device holes 511 of the substrate 510 to firmly fix the bonding ends 531 of the vertical probes 510 where the resins 550 are conductive paste to electrically connect the vertical probes 530 to the contacting pads 521 or other plated through holes of the trace layer 520. The probing ends 532 of the vertical probes 530 are protruded away from the substrate 510 for probing external terminals of untested IC chips.

The layout of a plurality of electrical contacting components 611 of the interposer 610 is corresponding to the one of the contacting pads of the substrate 510, not shown in the figure, and to the one of the inner pads 621 of the printed circuit board 620 to electrically connect the vertical probe head 500 to the printed circuit board 620. A plurality of internal circuits 622 and a plurality of pogo pads 623 are formed on the printed circuit board 620 to electrically connect the modularized probe card to the test head of a tester.

The vertical probe head 500 is attached to a metal assembling support 650 by an adhesive layer 651. A plurality of fixing elements 631 disposing on a pressure plate 640 are penetrated through the printed circuit board 620, through the through holes 612 of the interposer 610, and through the through holes of the vertical probe head 500 to accurately align the vertical probe head 500. Preferable, the assembling support 650 has a plurality of alignment holes 652 to fix the fixing elements 631 and to align the assembling support 650 with the vertical probe head 500. Moreover, a plurality of fixing elements 632, penetrating through the assembling support 650 and the printed circuit board 620, are used to fix the assembling support 650 assembled with the vertical probe head 500, the interposer 610, and the printed circuit board 620 to the pressure plate 640 to achieve good close contact between the assembling support 650 and the pressure plate 640. The vertical probe head 500, the interposer 610, and the printed circuit board 620 are assembled to form a modularized probe card.

The above description of embodiments of this invention is intended to be illustrative and not limiting. Other embodiments of this invention will be obvious to those skilled in the art in view of the above disclosure.

What is claimed is:

1. A vertical probe head comprising:
a substrate having a first surface, a second surface, and a plurality of device holes penetrating through the first surface and the second surface;
a trace layer forming on the first surface of the substrate; and
a plurality of vertical probes, each vertical probe having a bonding end and a probing end, wherein the bonding ends are inserted into the device holes of the substrate and are electrically connected to the trace layer, wherein the probing ends are protruded away from the second surface of the substrate.

2. The vertical probe head of claim 1, wherein the device holes are filled with resins to firmly fix the vertical probes.

3. The vertical probe head of claim 2, wherein the resins are non-conductive past (NCP).

4. The vertical probe head of claim 3, further comprising a plurality of soldering materials to electrically connect the bonding ends of the probes to the trace layer.

5. The vertical probe head of claim 2, wherein the resins are conductive paste.

6. The vertical probe head of claim 1, wherein the substrate is a semiconductor substrate.

7. The vertical probe head of claim 1, wherein the substrate is a flexible printed circuit board.

8. A method for manufacturing a vertical probe head, comprising;
providing a substrate having a first surface and a second surface with a trace layer formed on the first surface;
forming a plurality of device holes in the substrate, wherein the device holes penetrate through the first surface and the second surface; and
placing a plurality of vertical probes on the substrate, wherein each vertical probe has a bonding end and a probing end, wherein the bonding ends are inserted in the device holes of the substrate and are electrically connected to the trace layer, wherein the probing ends are protruded away from the second surface of the substrate.

9. The method of claim 8, further comprising the step of filling resins in the device holes to firmly fix the vertical probes.

10. The method of claim 8, wherein the probing ends of the vertical probes are connected by a connecting bar.

11. The method of claim 8, wherein the bonding ends of the vertical probes are connected by a same connecting bar.

12. A modularized probe card comprising:
a vertical probe head including:
a substrate having a first surface, a second surface, and a plurality of device holes penetrating through the first surface and the second surface;
a trace layer forming on the first surface of the substrate; and
a plurality of vertical probes, each probe having a bonding end and a probing end, wherein the bonding ends are inserted into the device holes of the substrate and are electrically connected to the trace layer, wherein the probing ends are protruded away from the second surface of the substrate;
a printed circuit board; and
an interposer disposed between the vertical probe head and the printed circuit board.

13. The modularized probe card of claim 12, further comprising an assembling support to joint the vertical probe head and the printed circuit board.

14. The modularized probe card of claim 13, further comprising a plurality of fixing elements and a pressure plate, wherein the assembling support has a plurality of through holes, wherein the fixing elements are fixed on the pressure plate by passing through the through holes of the assembling support.

15. The modularized probe card of claim 12, wherein the interposer includes a plurality of electrical contacting components to electrically connect the vertical probe head to the printed circuit board.

16. The modularized probe card of claim 15, wherein the electrical contacting components include pogo pins.

17. The modularized probe card of claim 12, wherein the device holes are filled with resins to firmly fix the vertical probes.

18. The modularized probe card of claim 12, wherein the substrate is a semiconductor substrate.

19. The modularized probe card of claim 18, wherein the material of the substrate is Si, SiGe, GaAs, or GaGe.

20. The modularized probe card of claim 12, wherein the substrate is a flexible printed circuit board.
